(19) United States
(12) Patent Application Publication
(10) Pub. No.: US 2026/0040661 A1
(43) Pub. Date: Feb. 5, 2026

(54) SEMICONDUCTOR DEVICE

(71) Applicant: FUJI ELECTRIC CO., LTD., Kawasaki-shi (JP)

(72) Inventor: Takahide TANAKA, Matsumoto-city (JP)

(73) Assignee: FUJI ELECTRIC CO., LTD., Kawasaki-shi (JP)

(21) Appl. No.: 19/250,549

(22) Filed: Jun. 26, 2025

(30) Foreign Application Priority Data
Aug. 1, 2024 (JP) 2024-125877

(51) Int. Cl. H10D 84/40

(52) U.S. Cl. CPC H10D 84/406

(57) ABSTRACT

A semiconductor device includes: a first semiconductor substrate of n-type; a high-side circuit including a first well region of p-type provided on a top surface side of the first semiconductor substrate; and a bootstrap diode including an anode region of p-type provided on the top surface side of the first semiconductor substrate separately from the first well region.

### CROSS-REFERENCE TO RELATED APPLICATION

This application claims benefit of priority under 35 USC 119 based on Japanese Patent Application No. 2024-125877 filed on Aug. 1, 2024, the entire contents of which are incorporated by reference herein.

### BACKGROUND OF THE INVENTION

### 1. Field of the Invention

The present disclosure relates to semiconductor devices.

### 2. Description of the Related Art

JP4610786B2 discloses a high-voltage integrated circuit (HVIC) internally including a bootstrap diode (BSD) provided with an anode region of p-type in an n-type region on a low-potential side.

JP4397602B2 discloses a HVIC internally including a BSD provided with a low-voltage diode in a low-side circuit region and an n-type diffusion resistor serving also as a voltage blocking region so as to be connected in series to each other.

The configuration disclosed in JP4610786B2 includes a vertical parasitic pnp bipolar transistor using the anode region in the BSD as an emitter. This configuration has a problem with the parasitic pnp bipolar transistor that operates every time the BSD is turned ON to cause a large amount of current to flow through.

The configuration disclosed in JP4397602B2 includes the low-voltage diode in the BSD arranged away from the n-type region to additionally provide a buried layer in this region in order to deal with the operation of the parasitic pnp bipolar transistor using the anode region in the BSD as an emitter. This measure, however, inevitably restricts the flexibility of design.

### SUMMARY OF THE INVENTION

In view of the foregoing problems, the present disclosure provides a semiconductor device having a configuration internally including a BSD capable of eliminating a problem of operation of a parasitic pnp bipolar transistor while improving a flexibility of design.

An aspect of the present disclosure inheres in a semiconductor device including: a first semiconductor substrate of n-type; a high-side circuit including a first well region of p-type provided on a top surface side of the first semiconductor substrate; and a bootstrap diode including an anode region of p-type provided on the top surface side of the first semiconductor substrate separately from the first well region.

### BRIEF DESCRIPTION OF THE DRAWINGS

FIG. 1 is a circuit diagram illustrating a semiconductor device according to a first embodiment;

FIG. 2 is a plan view illustrating the semiconductor device according to the first embodiment;

FIG. 3 is a cross-sectional view illustrating the semiconductor device according to the first embodiment taken along line A-A′ in FIG. 2;

FIG. 4 is a cross-sectional view illustrating the semiconductor device according to the first embodiment taken along line B-B′ in FIG. 2;

FIG. 5 is a cross-sectional view illustrating the semiconductor device according to the first embodiment taken along line C-C′ in FIG. 2;

FIG. 6 is a cross-sectional view illustrating the semiconductor device according to the first embodiment taken along line D-D′ in FIG. 2;

FIG. 7 is a circuit diagram illustrating a semiconductor device of a comparative example;

FIG. 8 is a plan view illustrating the semiconductor device of the comparative example;

FIG. 9 is a cross-sectional view illustrating the semiconductor device of the comparative example taken along line A-A′ in FIG. 8;

FIG. 10 is a circuit diagram illustrating a semiconductor device according to a second embodiment;

FIG. 11 is a plan view illustrating the semiconductor device according to the second embodiment; and

FIG. 12 is a cross-sectional view illustrating the semiconductor device according to the second embodiment taken along line A-A′ in FIG. 11.

### DETAILED DESCRIPTION

With reference to the drawings, first and second embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

The first and second embodiments described below merely illustrate schematically devices and methods for specifying and giving shapes to the technical idea of the present disclosure, and the span of the technical idea is not limited to materials, shapes, structures, and relative positions of elements described herein.

In the specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier reception region” means a semiconductor region which receive the majority carriers as the main current. The carrier reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type”, “second conductivity-type”, “n-type” and “p-type” in the following description indicate the members and the regions formed of semiconductor materials without particular obvious limitations. Further, in the appended claims, the term “n-type” as used herein encompasses any of n-type, n⁻-type, and n⁺-type, and the term “p-type” encompasses any of p-type, p⁻-type, and p⁺-type.

### First Embodiment

### Circuit of Semiconductor Device

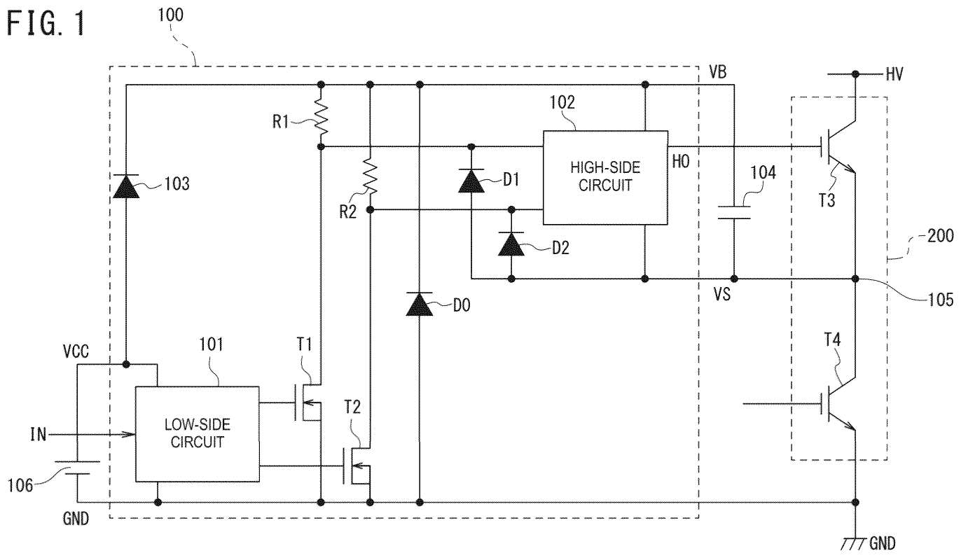

FIG. 1 is a circuit diagram illustrating a high-voltage integrated circuit (HVIC) 100 as an example of a semiconductor device according to a first embodiment. The HVIC 100 drives a power conversion part 200 for one phase as a target to be driven in a bridge circuit for power conversion, for example. The power conversion part 200 includes a high-potential side switching element T3 and a low-potential side switching element T4 connected in series so as to implement a half-bridge circuit. While FIG. 1 illustrates the case in which the high-potential side switching element T3 and the low-potential side switching element T4 are each an IGBT, the respective switching elements may be any other power switching element such as a metal-oxide-semiconductor field-effect transistor (MOSFET).

An HV potential on a high-potential side is connected to a collector of the high-potential side switching element T3. A ground potential (a GND potential) on a low-potential side is connected to an emitter of the low-potential side switching element T4. A load (not illustrated) such as a motor is connected to a VS potential which is a potential of a connection point 105 that is an intermediate point of the half-bridge circuit, between an emitter of the high-potential side switching element T3 and a collector of the low-potential side switching element T4

The HVIC 100 applies a drive signal, to a gate of the high-potential side switching element T3, for turning ON/OFF to drive the gate of the high-potential side switching element T3 in accordance with an input signal IN from an external microcomputer, for example. The HVIC 100 includes a low-potential side circuit (a low-side circuit) 101 and a high-potential side circuit (a high-side circuit) 102.

A VCC potential on the positive-electrode side of a power supply (a low-potential side power supply) 106 on the low-potential side and a GND potential on the negative-electrode side of the low-potential side power supply 106 are connected to the low-side circuit 101. Gates of level-shift elements (level shifters) T1 and T2 are also connected to the low-side circuit 101. The low-side circuit 101 operates with the GND potential used as a reference potential and with the VCC potential higher than the GND potential used as a power-supply potential. The low-side circuit 101 generates an ON/OFF signal based on the GND potential in accordance with the input signal IN from the external microcomputer or the like, and outputs the generated signal to the respective gates of the level shifters T1 and T2.

The high-side circuit 102 operates with the VS potential, which is the intermediate point potential in the half-bridge circuit used as a reference potential and with the VB potential higher than the VS potential used as a power-supply potential. The high-side circuit 102 outputs a drive signal based on the VS potential to the gate of the high-potential side switching element T3 in accordance with the ON/OFF signal from the respective level shifters T1 and T2 so as to drive the gate of the high-potential side switching element T3. The high-side circuit 102 includes, at the output stage, a CMOS circuit of an n-channel MOSFET and a p-channel MOSFET, for example.

The VB potential is a maximum potential to be applied to the HVIC 100, and is kept higher than the VS potential by about 15 volts in a normal operation not influenced by noise. The VS potential repeats a rise and a drop between the HV potential on the high-potential side (about 400 to 600 volts, for example) and the GND potential on the low-potential side when the high-potential side switching element T3 and the low-potential side switching element T4 are complementarily turned ON and OFF, and fluctuates between zero to several hundreds of volts. The VS potential can fall below zero.

The HVIC 100 includes a bootstrap circuit (103, 104) in order to use the low-potential side power supply 106 as a high-potential power supply. The bootstrap circuit (103, 104) includes a bootstrap diode (BSD) 103 and a bootstrap capacitor (BSC) 104. The VCC potential on the positive-electrode side of the low-potential side power supply 106 is connected to an anode of the BSD 103. A VB potential that is one end of the BSC 104 is connected to a cathode of the BSD 103. The VS potential of the connection point 105 is connected to the other end of the BSC 104. The BSD 103 prevents a current from flowing into the VCC potential when the VB potential is higher than the VCC potential. The BSD 103 is turned ON to charge the BSC 104 when the VB potential is led to be lower than the VCC potential.

The respective level shifters Tl and T2 transmit signals between the low-side circuit 101 and the high-side circuit 102. The respective level shifters T1 and T2 convert the ON/OFF signal based on the GND potential output from the low-side circuit 101 into an ON/OFF signal based on the VS potential, and outputs the converted ON/OFF signal to the high-side circuit 102. The respective level shifters T1 and T2 are implemented by a high-voltage n-channel MOSFET, for example.

The GND potential is connected to a source of the level shifter T1. The high-side circuit 102 and one end of a level-shift resistor R1 are connected to a drain of the level shifter T1. The cathode of the BSD 103 and the VB potential of one end of the BSC 104 are connected to the other end of the level-shift resistor R1. A cathode of a diode D1 is connected to the drain of the level shifter T1 and the one end of the level-shift resistor R1. The VS potential of the connection point 105 is connected to an anode of the diode D1. The diode D1 has a function capable of avoiding an excessive reduction in drain potential of the level shifter T1.

The GND potential is connected to a source of the level shifter T2. The high-side circuit 102 and one end of a level-shift resistor R2 are connected to a drain of the level shifter T2. The cathode of the BSD 103 and the VB potential of one end of the BSC 104 are connected to the other end of the level-shift resistor R2. A cathode of a diode D2 is connected to the drain of the level shifter T2 and the one end of the level-shift resistor R2. The VS potential of the connection point 105 is connected to an anode of the diode D2. The diode D2 has a function capable of avoiding an excessive reduction in drain potential of the level shifter T2.

A cathode of a high-voltage diode D0, which is referred to as a high-voltage junction termination (HVJT), is connected to the respective other ends of the level-shift resistors R1 and R2 and the VB potential of the one end of the BSC 104. The GND potential is connected to an anode of the diode D0.

### Configuration of Semiconductor Device

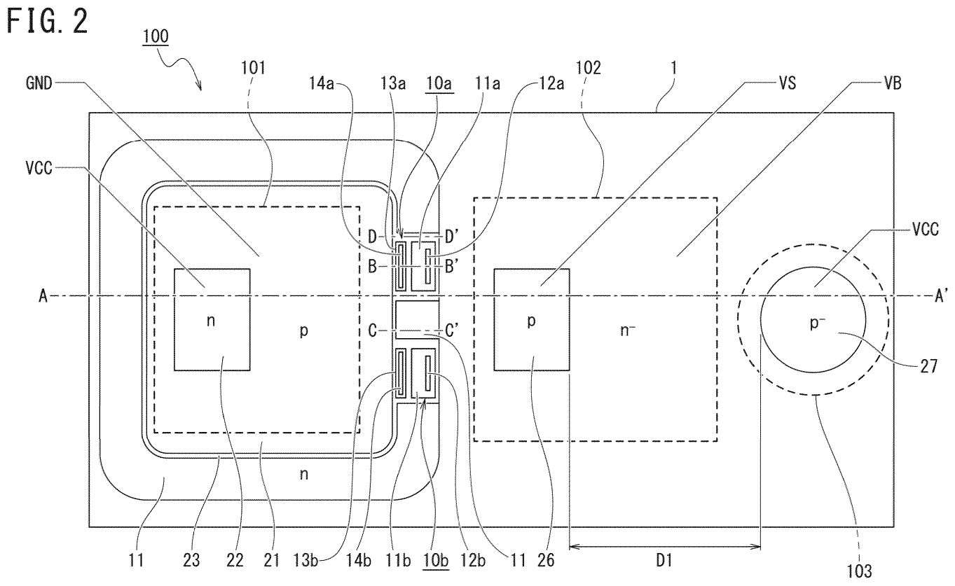

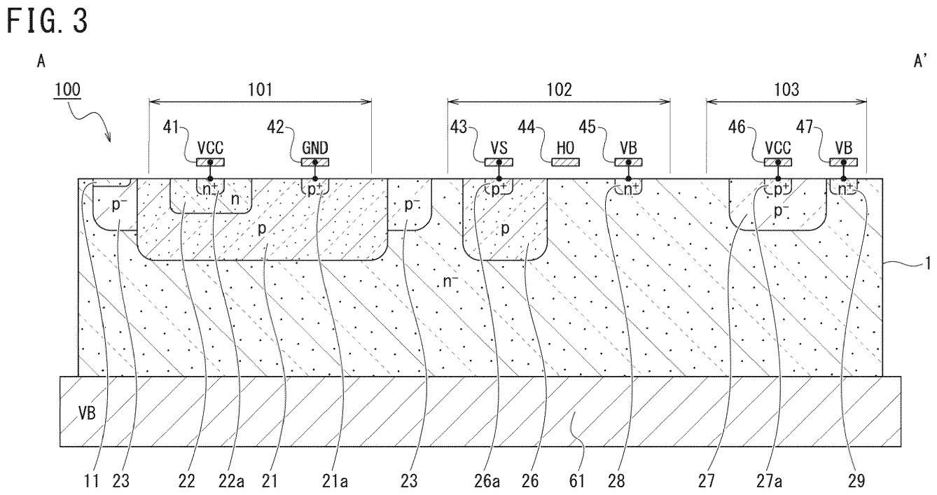

FIG. 2 is a planar layout of the semiconductor device according to the first embodiment corresponding to the HVIC 100 illustrated in FIG. 1. FIG. 3 is a cross-sectional view taken along line A-A′ in FIG. 2.

As illustrated in FIG. 2 and FIG. 3, the HVIC 100 includes a semiconductor substrate (a semiconductor chip) 1 of a first conductivity-type (n⁻-type). The semiconductor substrate 1 includes silicon (Si), for example. The semiconductor substrate 1 may include a wide bandgap semiconductor, such as silicon carbide (SiC), a gallium nitride (GaN), a gallium oxide (Ga₂O₃), gallium arsenide (GaAs), and diamond (C).

The semiconductor substrate 1 may be implemented by a semiconductor substrate (an epitaxial substrate) including a semiconductor substrate of n⁻-type and an epitaxial growth layer of n⁻-type grown on the semiconductor substrate. In such a case, the epitaxial growth layer may have substantially the same impurity concentration as the semiconductor substrate, or may have an impurity concentration that is either higher than or lower than that of the semiconductor substrate.

As illustrated in FIG. 2 and FIG. 3, a well region 21 of a second conductivity-type (p-type) is provided on the top surface side of the n⁻-type semiconductor substrate 1. The well region 21 has a substantially rectangular planar pattern. The planar pattern and the arranged position of the well region 21 can be changed as appropriate.

As illustrated in FIG. 3, a pickup region (a contact region) 21a of p⁺-type having a higher impurity concentration than the p-type well region 21 is provided on the top surface side of the p-type well region 21. A GND electrode 42, to which the GND potential that is the reference potential of the low-side circuit 101 is applied, is electrically connected to the pickup region 21a. The GND potential is applied to the well region 21 through the GND electrode 42 and the pickup region 21a. FIG. 2 omits the illustration of the GND electrode 42 and the pickup region 21a illustrated in FIG. 3. The planar pattern and the arranged position of each of the GND electrode 42 and the pickup region 21a can be changed as appropriate.

As illustrated in FIG. 2 and FIG. 3, a well region 22 of n-type is provided on the top surface side of the well region 21 so as to be in contact with each other. The well region 22 has a substantially rectangular planar pattern. The planar pattern and the arranged position of the well region 22 can be changed as appropriate.

As illustrated in FIG. 3, a pickup region (a contact region) 22a of n⁺-type having a higher impurity concentration than the well region 22 is provided on the top surface side of the well region 22. A VCC electrode 41, to which the VCC potential that is the power-supply potential of the low-side circuit 101 is applied, is electrically connected to the pickup region 22a. The VCC potential is applied to the well region 22 through the VCC electrode 41 and the pickup region 22a. FIG. 2 omits the illustration of the VCC electrode 41 and the pickup region 22a illustrated in FIG. 3. The planar pattern and the arranged position of each of the VCC electrode 41 and the pickup region 22a can be changed as appropriate.

The low-side circuit (the low-side circuit region) 101 is provided in the area corresponding to the well regions 21 and 22. FIG. 2 and FIG. 3 omit the illustration of the respective elements included in the low-side circuit 101.

As illustrated in FIG. 2 and FIG. 3, a voltage blocking region 23 of p⁻-type having a lower impurity concentration than the well region 21 is provided to surround the circumference of the well region 21 so as to be in contact with each other. The voltage blocking region 23 may have a shallower depth than the well region 21. The voltage blocking region 23 on the outer circumferential side is in contact with the semiconductor substrate 1.

A p-n junction between the voltage blocking region 23 and the semiconductor substrate 1 implements a high-voltage junction termination (HVJT) (1, 23). The HVJT (1, 23) corresponds to the high-voltage diode D0 illustrated in FIG. 1. The HVIT (1, 23) electrically isolates the low-side circuit 101 from the high-side circuit 102. The provision of the HVJT (1, 23) enables a normal operation of the semiconductor device regardless of whether the potential of the high-side circuit 102 is led to be higher than the potential of the low-side circuit 101 by several hundreds of volts.

As illustrated in FIG. 2 and FIG. 3, a well region 26 of p-type is provided on the top surface side of the semiconductor substrate 1 separately from the voltage blocking region 23. The well region 26 is in contact with the semiconductor substrate 1. The well region 26 has a substantially rectangular planar pattern. The planar pattern and the arranged position of the well region 26 can be changed as appropriate.

As illustrated in FIG. 3, a pickup region (a contact region) 26a of p⁺-type having a higher impurity concentration than the well region 26 is provided on the top surface side of the well region 26. A VS electrode 43, to which the VS potential that is the reference potential of the high-side circuit 102 is applied, is electrically connected to the pickup region 26a. The VS potential is applied to the well region 26 through the VS electrode 43 and the pickup region 26a. FIG. 2 omits the illustration of the VS electrode 43 and the pickup region 26a illustrated in FIG. 3. The planar pattern and the arranged position of each of the VS electrode 43 and the pickup region 26a can be changed as appropriate.

The high-side circuit (the high-side circuit region) 102 is provided in the area corresponding to a part of the semiconductor substrate 1 and the well region 26. FIG. 2 and FIG. 3 omit the illustration of the respective elements included in the high-side circuit 102.

As illustrated in FIG. 3, a pickup region (a contact region) 28 of n⁺-type having a higher impurity concentration than the semiconductor substrate 1 is provided on the top surface side of the semiconductor substrate 1 at a position corresponding to the high-side circuit 102. A VB electrode 45, to which the VB potential that is the power-supply potential of the high-side circuit 102 is applied, is electrically connected to the pickup region 28. The VB potential is applied to the semiconductor substrate 1 through the VB electrode 45 and the pickup region 28. FIG. 2 omits the illustration of the VB electrode 45 and the pickup region 28 illustrated in FIG. 3. The planar pattern and the arranged position of each of the VB electrode 45 and the pickup region 28 can be changed as appropriate.

As illustrated in FIG. 3, an HO electrode 44, to which an HO potential that is a potential at the output stage of the high-side circuit 102 is applied, is provided on the top surface side of the semiconductor substrate 1 at the position corresponding to the high-side circuit 102. FIG. 2 omits the illustration of the HO electrode 44 illustrated in FIG. 3. The planar pattern and the arranged position of the HO electrode 44 can be changed as appropriate.

As illustrated in FIG. 2 and FIG. 3, the BSD 103 is provided on the top surface side of the semiconductor substrate 1. The BSD 103 is located at a position so as to interpose the high-side circuit 102 between the BSD 103 and the low-side circuit 101 together. The BSD 103 includes an anode region 27 of p⁻-type provided on the top surface side of the semiconductor substrate 1 separately from the well region 26, and a cathode region implemented by a part of the semiconductor substrate 1 in contact with the anode region 27. The BSD 103 keeps the breakdown voltage, when the VB potential is higher than the VCC potential, such that a depletion layer expanding from a p-n junction between the anode region 27 and the semiconductor substrate 1 (the cathode region) is led to be depleted to a level so as not to reach the pickup region 27a or a pickup region 29. When the VB potential is led to be lower than the VCC potential, the BSD 103 is turned ON, so as to lead the current to flow from the VCC potential on the anode side toward the VB potential on the cathode side to charge the BSC 104 illustrated in FIG. 1.

The anode region 27 has a substantially circular planar pattern. The planar pattern of the anode region 27 is not limited to the circular shape, but may be a substantially rectangular shape, for example. The anode region 27 is located on the circumferential side of the high-side circuit 102 at a position farthest from the well region 26 in the high-side circuit 102, for example. The anode region 27 is away from the well region 26 in the high-side circuit 102 by a distance D1.

The anode region 27 may have substantially the same depth as the voltage blocking region 23. The anode region 27 may have substantially the same impurity concentration as the voltage blocking region 23. The anode region 27 and the voltage blocking region 23 can be formed simultaneously, so as to contribute to a decrease in the number of manufacturing steps. The anode region 27 may be formed independently of the voltage blocking region 23 instead. The depth of the anode region 27 may be either greater than or shallower than the depth of the voltage blocking region 23. The impurity concentration of the anode region 27 may be either higher than or lower than the impurity concentration of the voltage blocking region 23.

As illustrated in FIG. 3, a pickup region (a contact region) 27a of p⁺-type having a higher impurity concentration than the anode region 27 is provided on the top surface side of the anode region 27. A VCC electrode (the anode electrode) 46, to which the VCC potential that is the power-supply potential of the low-side circuit 101 is applied, is electrically connected to the pickup region 27a. The VCC potential is applied to the anode region 27 through the VCC electrode 46 and the pickup region 27a. FIG. 2 omits the illustration of the VCC electrode 46 and the pickup region 27a illustrated in FIG. 3. The planar pattern and the arranged position of each of the VCC electrode 46 and the pickup region 27a can be changed as appropriate.

The VCC electrode 46 may be electrically connected, via a bonding wire (a wire) or the like, to a lead frame to which the VCC potential is applied. The VCC electrode 46 may be electrically connected to the VCC electrode 41 in the low-side circuit 101 via a metal wire or the like.

As illustrated in FIG. 3, a pickup region (a contact region) 29 of n⁺-type having a higher impurity concentration than the semiconductor substrate 1 is provided on the top surface side of the semiconductor substrate 1 at a position corresponding to the cathode region of the BSD 103. A VB electrode (a cathode electrode) 47, to which the VB potential that is the power-supply potential of the high-side circuit 102 is applied, is electrically connected to the pickup region 29. FIG. 2 omits the illustration of the pickup region 29 and the VB electrode 47 illustrated in FIG. 3. The planar pattern and the arranged position of each of the pickup region 29 and the VB electrode 47 can be changed as appropriate. The pickup region 29 may have a loop-shaped planar pattern so as to surround the circumference of the anode region 27, for example.

The arranged position of the BSD 103 is not limited to the case as illustrated. For example, the BSD 103 may be arranged at a position interposing the low-side circuit 101 with the high-side circuit 102 together. In such a case, the VCC electrode 46 in the BSD 103 is located closer to the VCC electrode 41 in the low-side circuit 101, so as to decrease the length of the metal wire connecting the VCC electrode 46 and the VCC electrode 41 together.

As illustrated in FIG. 3, the semiconductor substrate 1 is mounted on and electrically connected to a lead frame 61 to which the VB potential is applied. The bottom surface of the semiconductor substrate 1 is in contact with the lead frame 61. The bottom surface side of the semiconductor substrate 1 may be provided with an electrode so as to be in contact with the lead frame 61. Alternatively, the semiconductor substrate 1 may be provided on a lead frame, to which a potential such as the GND potential different from the VB potential is applied, with an insulating adhesive or an insulating sheet interposed.

As illustrated in FIG. 2, a part of the voltage blocking region 23 on the low-side circuit 101 side is integrally provided with level shifters 10a and 10b. The respective level shifters 10a and 10b are implemented by a high-voltage n-channel MOSFET. The respective level shifters 10a and 10b correspond to the respective level shifters T1 and T2 illustrated in FIG. 1.

A method of forming the MOSFET implementing the respective level shifters T1 and T2 illustrated in FIG. 1 is broadly divided into two methods: one of which is referred to as a wire-bonding method (a WB method), and the other one is referred to as a self-shielding method (an SS method). The WB method forms the MOSFET independently of the HVJT (1, 23) so as to connect a drain potential (a Dr potential) of the MOSFET to the high-side circuit 102 via bonding wires. The SS method forms the MOSFET so as to integrate the HVJT (1, 23) with each other. Either method can be applied to the semiconductor device according to the first embodiment, but the present embodiment is illustrated below with the case in which the respective level shifters 10a and 10b are formed by the SS method.

The level shifters 10a and 10b are arranged in the voltage blocking region 23 on the side opposed to the high-side circuit 102. The arranged position of the respective level shifters 10a and 10b can be changed as appropriate.

The level shifter 10a includes a carrier reception region (a drain region) 11a of n-type, a pickup region (a contact region) 12a of n⁺-type provided on the top surface side of the drain region 11a and having a higher impurity concentration than the drain region 11a, a carrier supply region (a source region) 13a of n-type provided to be opposed to the drain region 11a, and a pickup region (a contact region) 14a of n⁺-type provided on the top surface side of the source region 13a and having a higher impurity concentration than the source region 13a.

The level shifter 10b includes a carrier reception region (a drain region) 11b of n-type, a pickup region (a contact region) 12b of n⁺-type provided on the top surface side of the drain region 11b and having a higher impurity concentration than the drain region 11b, a carrier supply region (a source region) 13b of n-type provided to be opposed to the drain region 11b, and a pickup region (a contact region) 14b of n⁺-type provided on the top surface side of the source region 13b and having a higher impurity concentration than the source region 13b.

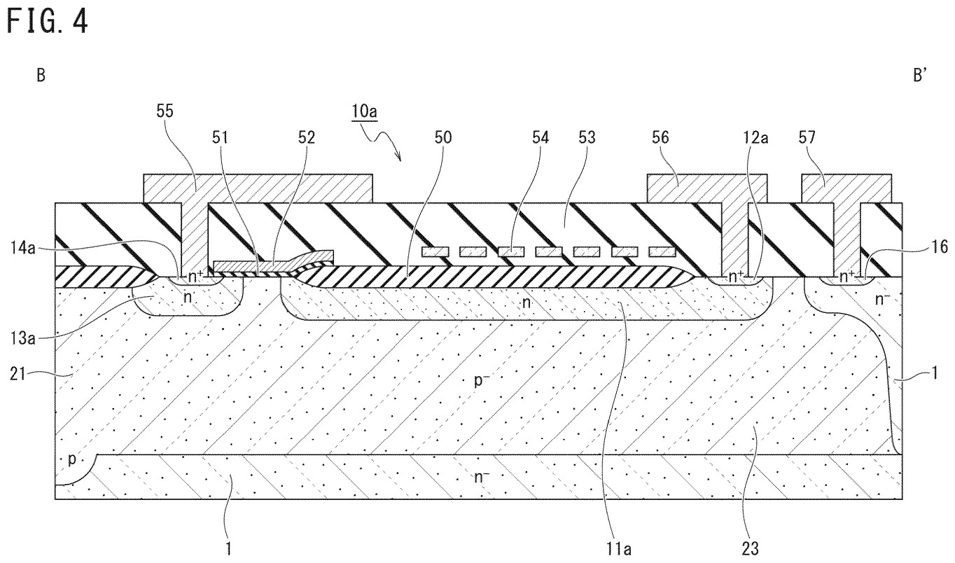

FIG. 4 is a cross-sectional view taken along line B-B′ passing through the level shifter 10a illustrated in FIG. 2. As illustrated in FIG. 4, the n-type drain region 11a is provided on the top surface side of the voltage blocking region 23. The n⁺-type pickup region 12a having a higher impurity concentration than the drain region 11a is provided on the top surface side of the drain region 11a. A drain electrode 56 is electrically connected to the pickup region 12a through a contact hole provided in an insulating film 53.

The n-type source region 13a is provided on the top surface side of the voltage blocking region 23 separately from the drain region 11a. The n⁺-type pickup region 14a having a higher impurity concentration than the source region 13a is provided on the top surface side of the source region 13a. A source electrode 55 is electrically connected to the pickup region 14a through a contact hole provided in the insulating film 53.

A gate electrode 52 is provided on the top surface side of the semiconductor substrate 1 with a gate insulating film 51 interposed at a part between the drain region 11a and the source region 13a. A resistive field plate 54 is provided over the top surface of the drain region 11a with the respective insulating films 50 and 53 interposed. The field plate 54 has a spiral-shaped planar pattern. A pickup region 16 of n⁺-type having a higher impurity concentration than the semiconductor substrate 1 is provided on the top surface side of the semiconductor substrate 1 on the outside of the drain region 11a. A VB electrode 57 is electrically connected to the pickup region 16 through a contact hole provided in the insulating film 53.

FIG. 2 omits the illustration of the pickup region 16, the source electrode 55, the drain electrode 56, the VB electrode 57, the insulating films 50 and 53, the gate insulating film 51, the gate electrode 52, and the field plate 54 illustrated in FIG. 4. The configuration of the level shifter 10b illustrated in FIG. 2 is substantially the same as that of the level shifter 10a illustrated in FIG. 4.

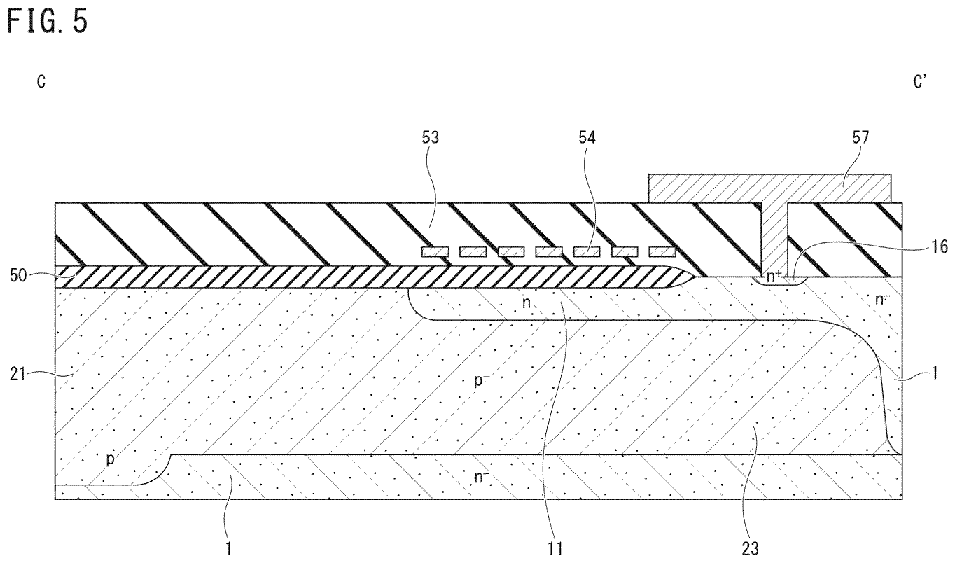

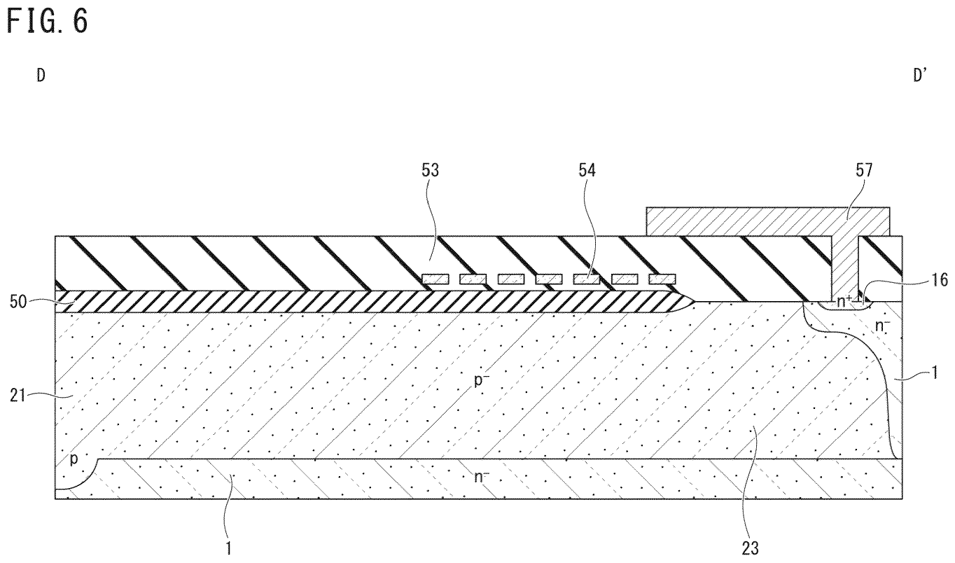

FIG. 5 is a cross-sectional view taken along line C-C′ in FIG. 2. As illustrated in FIG. 5, a diffusion region 11 of n-type is provided on the top surface side of the voltage blocking region 23 at a position immediately under the field plate 54. FIG. 6 is a cross-sectional view taken along line D-D′ in FIG. 2.

### Comparative Example

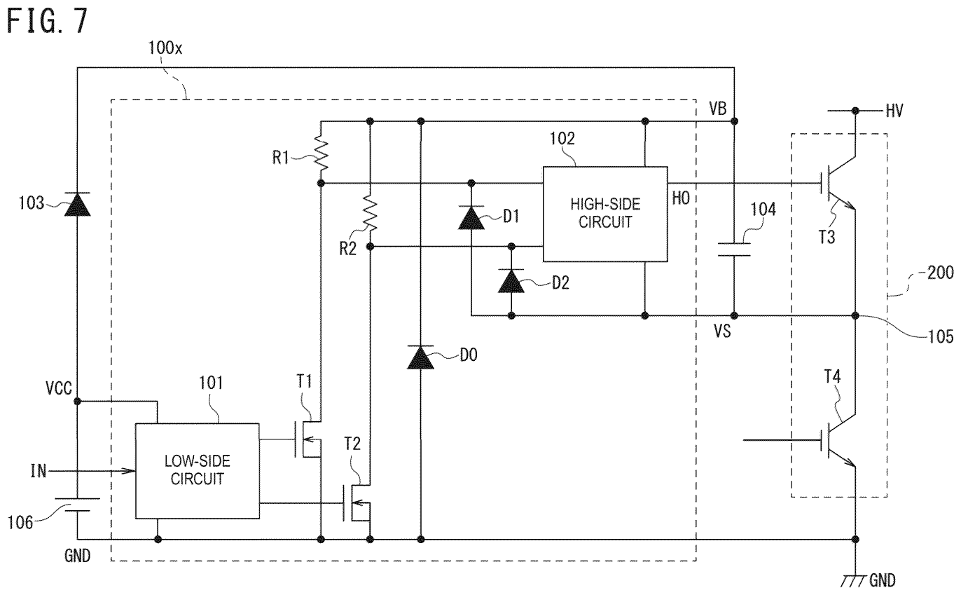

A semiconductor device of a comparative example is described below. FIG. 7 is a circuit diagram illustrating a HVIC 100x corresponding to the semiconductor device of the comparative example. As illustrated in FIG. 7, the HVIC 100x differs from the semiconductor device according to the first embodiment illustrated in FIG. 1 in not internally including the BSD 103 while being externally provided with the bootstrap circuit (103, 104).

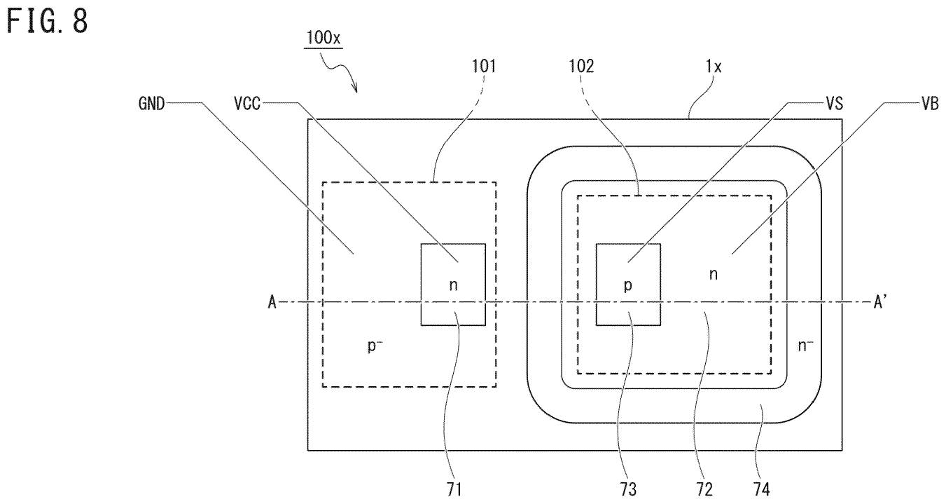

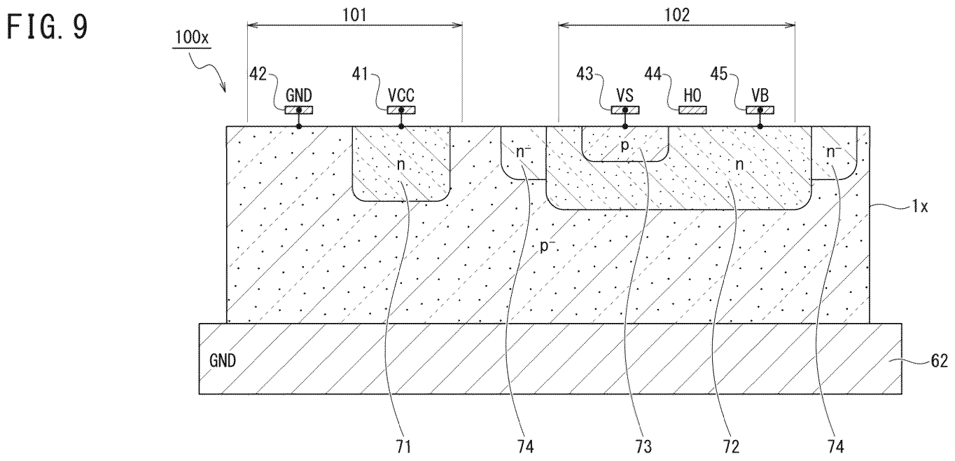

FIG. 8 is a planar layout illustrating the semiconductor device of the comparative example corresponding to the HVIC 100x illustrated in FIG. 7, and FIG. 9 is a cross-sectional view taken along line A-A′ in FIG. 8. As illustrated in FIG. 8 and FIG. 9, the HVIC 100x differs from the semiconductor device according to the first embodiment illustrated in FIG. 2 in that the HVIC 100x is formed in a p-type semiconductor substrate 1x.

A GND potential is applied to the semiconductor substrate 1x through the GND electrode 42 illustrated in FIG. 9. A well region 71 of n-type is provided on the top surface side of the semiconductor substrate 1x. The VCC potential is applied to the well region 71 through the VCC electrode 41 illustrated in FIG. 9. The low-side circuit 101 is provided in the area corresponding to a part of the semiconductor substrate 1x and the well region 71.

A well region 72 of n-type having a higher impurity concentration than the semiconductor substrate 1x is provided on the top surface side of the semiconductor substrate 1x. The VB potential is applied to the well region 72 through the VB electrode 45 illustrated in FIG. 9. A well region 73 of p-type is provided on the top surface side of the well region 72. The VS potential is applied to the well region 73 through the VS electrode 43 illustrated in FIG. 9. The high-side circuit 102 is provided in the area corresponding to the respective well regions 72 and 73. The HO electrode 44 is provide over the top surface side of the well region 72.

A voltage blocking region 74 of n⁻-type having a lower impurity concentration than the well region 72 is provided on the outer circumferential side of the well region 72. A p-n junction between the voltage blocking region 74 and the semiconductor substrate 1x implements a HVJT. The semiconductor substrate 1x is mounted on a lead frame 62 to which the GND potential is applied.

The semiconductor device of the comparative example illustrated in FIG. 7 to FIG. 9 includes the bootstrap circuit (103, 104) externally provided, which inevitably increases a packaging area. In contrast, the configuration of the semiconductor device according to the first embodiment, in which the HVIC 100 internally includes the BSD 103 of the bootstrap circuit (103, 104), can decrease the entire packaging area.

The configuration disclosed in JP4610786B2 internally includes the BSD, but is thus led to provide the vertical parasitic pnp bipolar transistor using the anode region of the BSD as an emitter. In contrast, the configuration of the semiconductor device according to the first embodiment, which includes the n⁻-type semiconductor substrate 1, does not provide a vertical parasitic pnp bipolar transistor that would use the anode region 27 of the BSD 103 as an emitter, so as to eliminate a problem of operation of such a vertical parasitic pnp bipolar transistor.

The HVIC disclosed in JP4397602B2 is configured to suppress an operation of a vertical parasitic pnp bipolar transistor, and the configuration thus causes a problem of flexibility of design. In contrast, the configuration of the semiconductor device according to the first embodiment can keep the anode region 27 in the BSD 103 away from the well region 26 applied with the VS potential and the well region 21 applied with the GND potential that could be a collector of a parasitic pnp bipolar transistor using the anode region 27 as an emitter, so as to enhance the flexibility of design.

Further, the configuration of the semiconductor device according to the first embodiment includes the BSD 103 at the position so as to interpose the high-side circuit 102 between the BSD 103 and the low-side circuit 101. This configuration can lead the anode region 27 to be located away from the p-type well region 21 in the low-side circuit 101, so as to eliminate a problem of operation of a parasitic pnp bipolar transistor that would use the anode region 27 as an emitter, the semiconductor substrate 1 as a base, and the well region 21 as a collector.

Further, the configuration of the semiconductor device according to the first embodiment includes the BSD 103 on the circumferential side of the high-side circuit 102 at the position away from the p-type well region 26. This configuration can eliminate a problem of operation of a parasitic pnp bipolar transistor using the anode region 27 as an emitter, the semiconductor substrate 1 as a base, and the well region 26 as a collector.

### Second Embodiment

### Circuit of Semiconductor Device

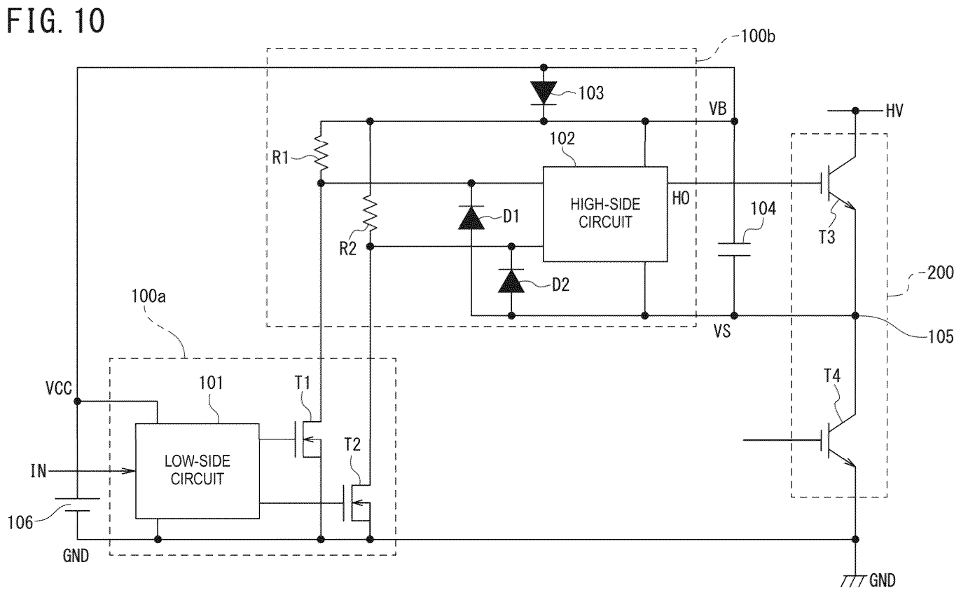

FIG. 10 is a circuit diagram illustrating a HVIC (100a, 100b) as an example of a semiconductor device according to a second embodiment. As illustrated in FIG. 10, the HVIC (100a, 100b) differs from the semiconductor device according to the first embodiment illustrated in FIG. 1 in being divided into two semiconductor chips 100a and 100b.

The semiconductor chip 100a includes the low-side circuit 101 and the level shifters T1 and T2. The semiconductor chip 100b includes the high-side circuit 102, the BSD 103, the level-shift resistors R1 and R2, and the diodes D1 and D2. The present embodiment does not include the diode D0 implementing the HVJT for electrically isolating the low-side circuit 101 from the high-side circuit 102, since the low-side circuit 101 and the high-side circuit 102 are provided independently in the semiconductor chips 100a and 100b. The other circuit configurations of the semiconductor device according to the second embodiment are substantially the same as those of the semiconductor device according to the first embodiment illustrated in FIG. 1, and overlapping explanations are not repeated below.

### Configuration of Semiconductor Device

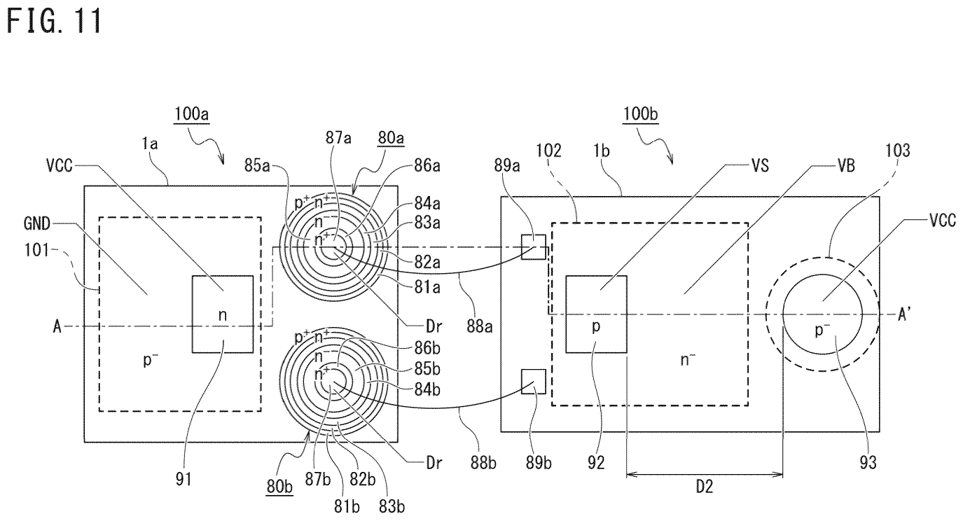

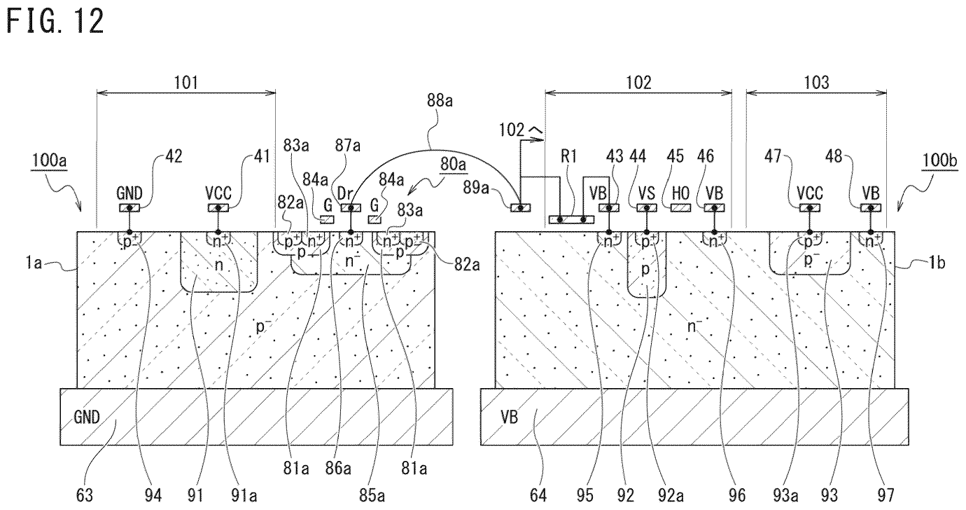

FIG. 11 is a planar layout of the semiconductor device according to the second embodiment corresponding to the HVIC (100a, 100b) illustrated in FIG. 10. FIG. 12 is a cross-sectional view taken along line A-A′ in FIG. 11. As illustrated in FIG. 11 and FIG. 12, the HVIC (100a, 100b) includes the two semiconductor chips 100a and 100b. The semiconductor chips 100a and 100b are arranged separately from each other.

The semiconductor chip 100a includes a semiconductor substrate 1a of p⁻-type. The semiconductor chip 100a includes silicon (Si), for example. The semiconductor substrate 1a may include a wide bandgap semiconductor such as silicon carbide (SiC), a gallium nitride (GaN), a gallium oxide (Ga₂O₃), gallium arsenide (GaAs), and diamond (C).

The semiconductor substrate 1a may be implemented by a semiconductor substrate (an epitaxial substrate) including a semiconductor substrate of p⁻-type and an epitaxial growth layer of p⁻-type grown on the semiconductor substrate. In such a case, the epitaxial growth layer may have substantially the same impurity concentration as the semiconductor substrate, or may have an impurity concentration that is either higher than or lower than that of the semiconductor substrate.

As illustrated in FIG. 11 and FIG. 12, a well region 91 of n-type is provided on the top surface side of the semiconductor substrate 1a. The well region 91 has a substantially rectangular planar pattern. The planar pattern and the arranged position of the well region 91 can be changed as appropriate.

As illustrated in FIG. 12, a pickup region (a contact region) 91a of n⁺-type having a higher impurity concentration than the well region 91 is provided on the top surface side of the well region 91. The VCC electrode 41, to which the VCC potential that is the power-supply potential of the low-side circuit 101 is applied, is electrically connected to the pickup region 91a. The VCC potential is applied to the well region 91 through the VCC electrode 41 and the pickup region 91a. FIG. 11 omits the illustration of the VCC electrode 41 and the pickup region 91a illustrated in FIG. 12. The planar pattern and the arranged position of each of the VCC electrode 41 and the pickup region 91a can be changed as appropriate.

The low-side circuit 101 is provided in the area corresponding to a part of the semiconductor substrate 1a and the well region 91. FIG. 11 and FIG. 12 omit the illustration of the respective elements included in the low-side circuit 101.

As illustrated in FIG. 12, a pickup region (a contact region) 94 of p⁺-type having a higher impurity concentration than the p⁻-type semiconductor substrate 1a is provided on the top surface side of the semiconductor substrate 1a at the position corresponding to the low-side circuit 101. The GND electrode 42, to which the GND potential that is the reference potential of the low-side circuit 101 is applied, is electrically connected to the pickup region 94. The GND potential is applied to the semiconductor substrate la through the GND electrode 42 and the pickup region 94. FIG. 11 omits the illustration of the GND electrode 42 and the pickup region 94 illustrated in FIG. 12. The planar pattern and the arranged position of each of the GND electrode 42 and the pickup region 94 can be changed as appropriate.

As illustrated in FIG. 11, the semiconductor chip 100a includes level shifters 80a and 80b formed by the WB method. The respective level shifters 80a and 80b have a substantially circular planar pattern. The respective level shifters 80a and 80b are implemented by a high-voltage n-channel MOSFET.

The level shifter 80a includes a base region 81a of p-type, a pickup region (a contact region) 82a of p⁺-type, a carrier supply region (a source region) 83a of n⁺-type, a gate electrode 84a, a drift region 85a of n⁻-type, and a carrier reception region (a drain region) 86a of n⁺-type. The base region 81a has a loop-shaped planar pattern. The pickup region 82a and the source region 83a are provided inside the base region 81a so as to have a loop-shaped planar pattern. The drift region 85a is provided to be in contact with the base region 81a so as to have a circular planar pattern. While a depth of the drift region 85a is shallower than that of the well region 91, the depth of the drift region 85a may be set to be greater than or equal to that of the well region 91.

The gate electrode 84a is arranged over the loop-shaped p-type base region 81a interposed between the source region 83a and the drift region 85a with a gate insulating film (not illustrated) interposed. The drain region 86a is provided on the top surface side of the drift region 85a and has a circular planar pattern. A drain electrode 87a is provided on the top surface side of the top surface of the drain region 86a. A pad 89a in the semiconductor chip 100b is connected to the drain electrode 87a via a bonding wire 88a.

As illustrated in FIG. 11, the level shifter 80b includes a base region 81b of p-type, a pickup region (a contact region) 82b of p⁺-type, a carrier supply region (a source region) 83b of n⁺-type, a gate electrode 84b, a drift region 85b of n⁻-type, and a carrier reception region (a drain region) 86b of n⁺-type. The base region 81b has a loop-shaped planar pattern. The pickup region 82b and the source region 83b are provided inside the base region 81b so as to have a loop-shaped planar pattern. The drift region 85b is provided to be in contact with the base region 81b so as to have a circular planar pattern. A depth of the drift region 85b may be set to be greater than that of the well region 91.

The gate electrode 84b is arranged over the loop-shaped p-type base region 81b between the source region 83b and the drift region 85b with a gate insulating film (not illustrated) interposed. The drain region 86b is provided on the top surface side of the drift region 85b and has a circular planar pattern. A drain electrode 87b is provided over the top surface side of the drain region 86b. A pad 89b in the semiconductor chip 100b is connected to the drain electrode 87b via a bonding wire 88b.

As illustrated in FIG. 12, the semiconductor substrate 1a is mounted on and electrically connected to a lead frame 63 to which the GND potential is applied. The bottom surface of the semiconductor substrate 1a is in contact with the lead frame 63. The bottom surface side of the semiconductor substrate 1a may be provided with an electrode so as to be in contact with the lead frame 63. Alternatively, the semiconductor substrate 1a may be provided on a lead frame, to which a potential different from the GND potential is applied, with an insulating adhesive or an insulating sheet interposed.

As illustrated in FIG. 11 and FIG. 12, the semiconductor chip 100b includes a semiconductor substrate 1b of n⁻-type. The semiconductor substrate 1b has substantially the same configuration as the semiconductor substrate 1 in the semiconductor device according to the first embodiment.

As illustrated in FIG. 11 and FIG. 12, a well region 92 of p-type is provided on the top surface side of the semiconductor substrate 1b. The well region 92 has a substantially rectangular planar pattern. The planar pattern and the arranged position of the well region 92 can be changed as appropriate.

As illustrated in FIG. 12, a pickup region (a contact region) 92a of p⁺-type having a higher impurity concentration than the well region 92 is provided on the top surface side of the well region 92. A VS electrode 44, to which the VS potential that is the reference potential of the high-side circuit 102 is applied, is electrically connected to the pickup region 92a. The VS potential is applied to the well region 92 through the VS electrode 44 and the pickup region 92a. FIG. 11 omits the illustration of the VS electrode 44 and the pickup region 92a illustrated in FIG. 12. The planar pattern and the arranged position of each of the VS electrode 44 and the pickup region 92a can be changed as appropriate.

The high-side circuit 102 is provided in the area corresponding to a part of the semiconductor substrate 1b and the well region 92. FIG. 11 and FIG. 12 omit the illustration of the respective elements included in the high-side circuit 102.

As illustrated in FIG. 12, a pickup region (a contact region) 96 of n⁺-type having a higher impurity concentration than the semiconductor substrate 1b is provided on the top surface side of the semiconductor substrate 1b at a position corresponding to the high-side circuit 102. A VB electrode 46, to which the VB potential that is the power-supply potential of the high-side circuit 102 is applied, is electrically connected to the pickup region 96. The VB potential is applied to the semiconductor substrate 1b through the VB electrode 46 and the pickup region 96. FIG. 11 omits the illustration of the VB electrode 46 and the pickup region 96 illustrated in FIG. 12. The planar pattern and the arranged position of each of the VB electrode 46 and the pickup region 96 can be changed as appropriate.

As illustrated in FIG. 12, an HO electrode 45, to which the HO potential that is the potential at the output stage of the high-side circuit 102 is applied, is provided on the top surface side of the semiconductor substrate 1b at the position corresponding to the high-side circuit 102. FIG. 11 omits the illustration of the HO electrode 45 illustrated in FIG. 12. The planar pattern and the arranged position of the HO electrode 45 can be changed as appropriate.

As illustrated in FIG. 11 and FIG. 12, the pads 89a and 89b are provided at the positions in the semiconductor chip 100b on the side opposed to the semiconductor chip 100a. As illustrated in FIG. 12, the pad 89a on the top surface side of the semiconductor substrate 1b is electrically connected to the level-shift resistor R1. The pad 89a is also connected to a gate electrode (not illustrated) of the MOSFET, for example, inside the high-side circuit 102. The level-shift resistor R1 is electrically connected to the VB electrode 43. The VB electrode 43 is electrically connected to a pickup region (a contact region) 95 of n⁺-type having a higher impurity concentration than the semiconductor substrate 1b. FIG. 11 omits the illustration of the pickup region 95 illustrated in FIG. 12. The planar pattern and the arranged position of the pickup region 95 can be changed as appropriate.

As illustrated in FIG. 11 and FIG. 12, the BSD 103 is provided on the top surface side of the semiconductor substrate 1b. The BSD 103 is arranged on the circumferential side of the high-side circuit 102 at a position away from the p-type well region 92. The arranged position of the BSD 103 is not limited to this case as illustrated. The BSD 103 includes an anode region 93 of p⁻-type provided on the top surface side of the semiconductor substrate 1b separately from the well region 92, and a cathode region implemented by a part of the semiconductor substrate 1b in contact with the anode region 93.

As illustrated in FIG. 12, a pickup region (a contact region) 93a of p⁺-type having a higher impurity concentration than the anode region 93 is provided on the top surface side of the anode region 93. A VCC electrode 47, to which the VCC potential that is the power-supply potential of the low-side circuit 101 is applied, is electrically connected to the pickup region 93a. The VCC potential is applied to the anode region 93 through the VCC electrode 47 and the pickup region 93a. FIG. 11 omits the illustration of the VCC electrode 47 and the pickup region 93a illustrated in FIG. 12. The planar pattern and the arranged position of each of the VCC electrode 47 and the pickup region 93a can be changed as appropriate. The VCC electrode 47 may be electrically connected, via a bonding wire or the like, to a lead frame to which the VCC potential is applied.

As illustrated in FIG. 12, a pickup region (a contact region) 97 of n⁺-type having a higher impurity concentration than the semiconductor substrate 1b is provided on the top surface side of the semiconductor substrate 1b at a position corresponding to the cathode region in the BSD 103. A VB electrode 48, to which the VB potential that is the power-supply potential of the high-side circuit 102 is applied, is electrically connected to the pickup region 97. The VB potential is applied to the cathode region of the BSD 103 through the VB electrode 48 and the pickup region 97. FIG. 11 omits the illustration of the VB electrode 48 and the pickup region 97 illustrated in FIG. 12. The planar pattern and the arranged position of each of the VB electrode 48 and the pickup region 97 can be changed as appropriate. The pickup region 97 may have a loop-shaped planar pattern so as to surround the circumference of the anode region 93, for example.

As illustrated in FIG. 12, the semiconductor substrate 1b is mounted on and electrically connected to a lead frame 64 to which the VB potential is applied. The bottom surface of the semiconductor substrate 1b is in contact with the lead frame 64. The bottom surface side of the semiconductor substrate 1b may be provided with an electrode so as to be in contact with the lead frame 64. Alternatively, the semiconductor substrate 1b may be provided on a lead frame, to which a potential different from the VB potential is applied, with an insulating adhesive or an insulating sheet interposed. The other configurations of the semiconductor device according to the second embodiment are substantially the same as those of the semiconductor device according to the first embodiment, and overlapping explanations are not repeated below.

The configuration of the semiconductor device according to the second embodiment, in which the HVIC (100a, 100b) internally includes the BSD 103 of the bootstrap circuit (103, 104), can decrease the packaging area. Further, the semiconductor device according to the second embodiment has the configuration in which the HVIC (100a, 100b) is divided into the semiconductor chip 100a provided with the low-side circuit 101 in the p⁻-type semiconductor substrate 1a and the semiconductor chip 100b provided with the high-side circuit 102 and the BSD 103 in the n⁻-type semiconductor substrate 1b. This configuration does not need to provide the HVJT for electrically isolating the low-side circuit 101 from the high-side circuit 102, so as to contribute to a reduction in chip size.

Further, the configuration of the semiconductor device according to the second embodiment, which includes the high-side circuit 102 and the BSD 103 in the n⁻-type semiconductor substrate 1b, eliminates a provision of a vertical parasitic pnp bipolar transistor that would use the anode region 93 of the BSD 103 as an emitter, so as to prevent the operation of such a vertical parasitic pnp bipolar transistor.

Further, the configuration of the semiconductor device according to the second embodiment can keep the anode region 93 of the BSD 103 by the distance D2 away from the well region 92 applied with the VS potential that could serve as a collector of a parasitic pnp bipolar transistor using the anode region 93 of the BSD 103 as an emitter, so as to improve the flexibility of design accordingly.

Further, the semiconductor device according to the second embodiment has the configuration in which the BSD 103 is provided on the circumferential side of the high-side circuit 102 at the position away from the p-type well region 92. This configuration can eliminate a problem of operation of a parasitic pnp bipolar transistor that would use the anode region 93 as an emitter, the semiconductor substrate 1b as a base, and the well region 92 as a collector.

### Other Embodiments

As described above, the invention has been described according to the first and second embodiments, but it should not be understood that the description and drawings implementing a portion of this disclosure limit the invention. Various alternative embodiments of the present disclosure, examples, and operational techniques will be apparent to those skilled in the art from this disclosure.

For example, while the respective semiconductor devices according to the first and second embodiments are illustrated above with the configuration including the low-side circuit 101, the high-side circuit 102, and the BSD 103 for one phase, the present disclosure is not limited to this case, and may be applied to a configuration including low-side circuits, high-side circuits, and BSDs for three phases.

When the semiconductor device according to the first embodiment is used for a case for three phases, three semiconductor chips each provided with a low-side circuit, a high-side circuit, and a BSD for one phase can be used. When the semiconductor device according to the second embodiment is used for a case for three phases, three sets each including a single semiconductor chip provided with a low-side circuit for one phase and a single semiconductor chip provided with a high-side circuit and a BSD for one phase can be used. Alternatively, a single semiconductor chip provided with low-side circuits for three phases integrated together and three semiconductor chips each provided with a high-side circuit and a BSD for one phase can be used.

In addition, the respective configurations disclosed in the first and second embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a first semiconductor substrate of n-type;
a high-side circuit including a first well region of p-type provided on a top surface side of the first semiconductor substrate; and
a bootstrap diode including an anode region of p-type provided on the top surface side of the first semiconductor substrate separately from the first well region.

2. The semiconductor device of claim 1, further comprising a low-side circuit including a second well region of p-type provided on the top surface side of the first semiconductor substrate separately from the first well region and the anode region, and a third well region of n-type provided on a top surface side of the second well region.

3. The semiconductor device of claim 1, wherein the first semiconductor substrate is electrically connected to a lead frame to which a power-supply potential of the high-side circuit is applied.

4. The semiconductor device of claim 2, wherein the bootstrap diode is arranged at a position so as to interpose the high-side circuit between the bootstrap diode and the low-side circuit.

5. The semiconductor device of claim 1, wherein the bootstrap diode is arranged at a circumference of the high-side circuit at a position away from the first well region.

6. The semiconductor device of claim 1, further comprising a level shifter provided in the first semiconductor substrate to transmit a signal between the low-side circuit and the high-side circuit.

7. The semiconductor device of claim 1, further comprising a voltage blocking region of p-type provided in contact with the second well region and having a lower impurity concentration than the second well region.

8. The semiconductor device of claim 1, further comprising:
a second semiconductor substrate of p-type; and
a low-side circuit including a fourth well region of n-type provided on a top surface side of the second semiconductor substrate,
wherein the low-side circuit is connected to the high-side circuit via a wire.

9. The semiconductor device of claim 8, wherein:
the first semiconductor substrate is electrically connected to a lead frame to which a power-supply potential of the high-side circuit is applied; and
the second semiconductor substrate is electrically connected to a lead frame to which a reference potential of the low-side circuit is applied.

10. The semiconductor device of claim 8, further comprising a level shifter provided in the second semiconductor substrate to transmit a signal between the low-side circuit and the high-side circuit.

11. The semiconductor device of claim 2, wherein the bootstrap diode on an anode side is connected to a reference potential of the low-side circuit, and the bootstrap diode on a cathode side is connected to a power-supply potential of the high-side circuit.

12. The semiconductor device of claim 8, wherein the bootstrap diode on an anode side is connected to a reference potential of the low-side circuit, and the bootstrap diode on a cathode side is connected to a power-supply potential of the high-side circuit.
